(19) United States
(12) Patent Application Publication
(10) Pub. No.: US 2008/0157844 A1
(43) Pub. Date: Jul. 3, 2008

(54) TIME DELAY CIRCUIT

(75) Inventor: ZE-SHU REN, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/766,107

(22) Filed: Jun. 21, 2007

(30) Foreign Application Priority Data
Dec. 29, 2006 (CN) 200610064634.9

(51) Int. Cl. H03H 11/26

(52) U.S. Cl. 327/290

(57) ABSTRACT

A time delay circuit includes an RC circuit with a resistor and a capacitor connected, and a switch. The switch includes a first terminal, a second terminal, and a control terminal for controlling conduction of the first and second terminals. The first terminal is connected to an end of the resistor, which is connected to the capacitor. The second terminal is connected to ground, and the control terminal is connected to the other end of the resistor configured for receiving an input signal. When the input signal changes from logical low to logical high to turn off the switch, the capacitor is charged to a predetermined value with a predetermined rise time beginning from the change of the input signal. When the input signal changes from logical high to logical low to turn on the switch, the first and second terminals of the switch conduct to quickly discharge the capacitor to the predetermined value substantially synchronized with the change of the input signal.

### BACKGROUND OF THE INVENTION

1. Field of the Invention

The present invention relates to a time delay circuit, and more particularly to a time delay circuit composed of an RC (resistor and capacitor) circuit.

2. Description of Related Art

RC circuits serve as time delay circuits in many applications. FIGS. 5 and 6 show a circuit and corresponding sequence chart of the circuit with a normal time delay circuit 80 used therein. The circuit includes an input terminal 10 and an output terminal 11. The time delay circuit 80 connects the input terminal 10 to a gate terminal G of a transistor Q11, which is of the N channel junction field effect type. The time delay circuit 80 includes a resistor R11 and a capacitor C11. A source terminal S of the transistor Q11 is connected to ground. The output terminal 11 is connected to a drain terminal D of the transistor Q11. The drain terminal D further connects to a node 13 via a resistor R12. A high-level voltage signal is applied to the node 13.

Referring to FIG. 6, at time T1, a high-level voltage signal of 5V is input to the input terminal 10. The capacitor C11 begins to charge. At time T2, the voltage of the capacitor C11 rises to 2V, which is equal to a threshold voltage of the transistor Q11. The voltage of the gate terminal G of the transistor Q11 is 2V. The transistor Q11 is turned on to connect the drain terminal D of the transistor Q11 to ground. Therefore, the output terminal 11 outputs a low-level voltage signal. The output of the low-level voltage signal of the output terminal 11 is delayed by a period of (T2-T1) relative to the input of the input terminal 10.

At time T3, a low-level voltage signal is input to the input terminal 10. The capacitor C11 begins to discharge, and the voltage of the capacitor C11 begins to decrease. At time T4, the voltage of the capacitor C11 declines below the threshold voltage of the transistor Q11. The transistor Q11 is turned off, and so the output terminal 11 outputs a high-level voltage signal. The output of the high-level voltage signal of the output terminal 11 is delayed by a period of (T4-T3) relative to the input of the input terminal 10.

In the above circuit, outputs are delayed relative to both the high and the low-level voltage inputs. However, in some situations, an output only needs to be delayed relative to the high-level voltage input, and synchronized with the low-level voltage input. The normal time delay circuit 80 does not meet this need.

### SUMMARY OF THE INVENTION

A time delay circuit includes an RC circuit with a resistor and a capacitor connected, and a switch. The switch includes a first terminal, a second terminal, and a control terminal for controlling conduction of the first and second terminals. The first terminal is connected to an end of the resistor, which is connected to the capacitor. The second terminal is connected to ground, and the control terminal is connected to the other end of the resistor configured for receiving an input signal. When the input signal changes from logical low to logical high to turn off the switch, the capacitor is charged to a predetermined value with a predetermined rise time beginning from the change of the input signal. When the input signal changes from logical high to logical low to turn on the switch, the first and second terminals of the switch conduct to quickly discharge the capacitor to the predetermined value substantially synchronized with the change of the input signal.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is a circuit including a time delay circuit in accordance with a first embodiment of the present invention;

FIG. 2 is a sequence chart of the circuit of FIG. 1;

FIG. 3 is a circuit including a time delay circuit in accordance with a second embodiment of the present invention;

FIG. 4 is a circuit including a time delay circuit in accordance with a third embodiment of the present invention;

FIG. 5 is a circuit including a conventional time delay circuit; and

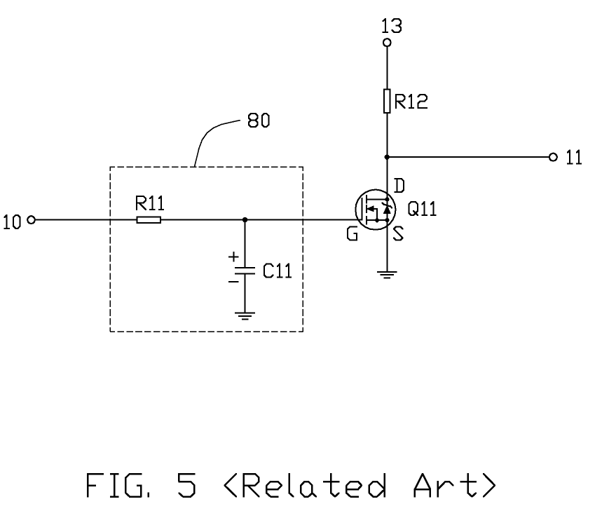

FIG. 6 is a sequence chart of the circuit of FIG. 5.

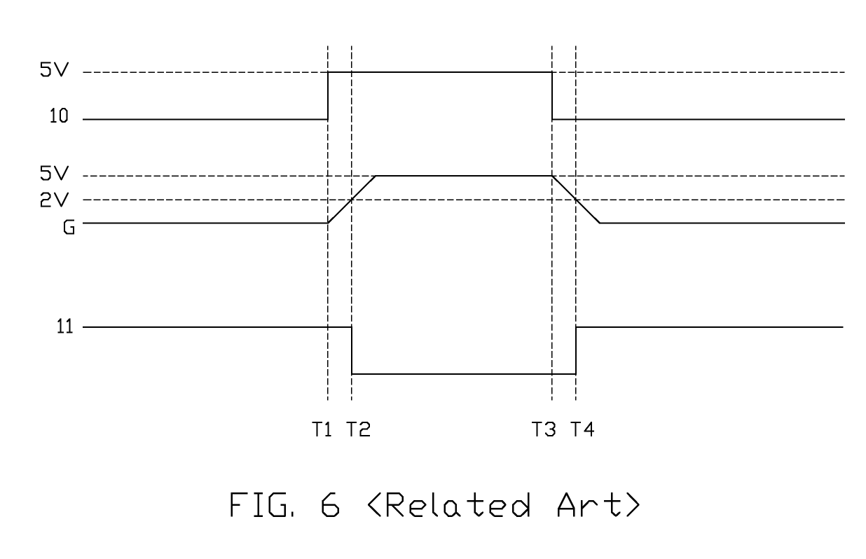

### DETAILED DESCRIPTION OF THE INVENTION

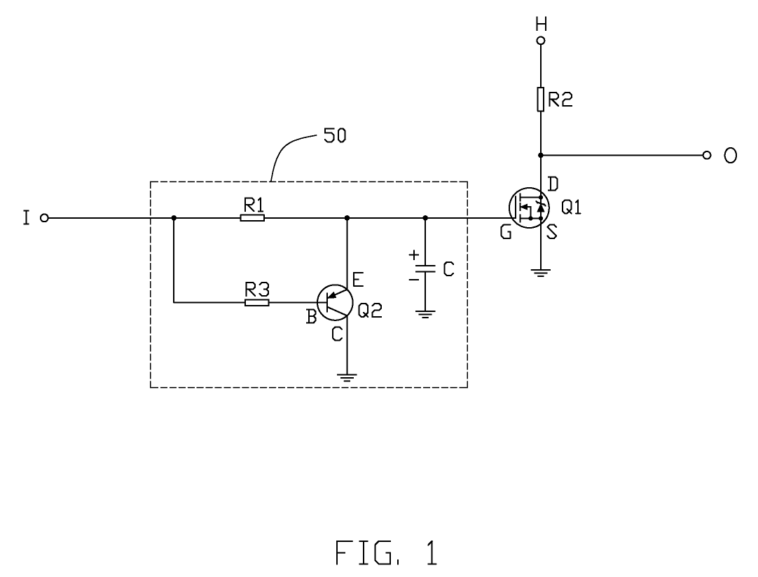

Referring to FIG. 1, a circuit with a time delay circuit 50 in accordance with a first embodiment of the present invention is shown. The circuit includes an input terminal I and an output terminal O. The time delay circuit 50 connects the input terminal I to a gate terminal G of a transistor Q1, which is of the N channel junction field effect type. The time delay circuit 50 includes a resistor R1, a capacitor C, and a switch that turns on when a low-level voltage signal is applied thereto, and turns off when a high-level voltage signal is applied thereto. In the first embodiment of the present embodiment, the switch is a PNP type transistor Q2. A base terminal B of the transistor Q2 is connected to an end of the resistor R1, which is connected to the input terminal I, via a resistor R3. An emitter terminal E of the transistor Q2 is connected to the other end of the resistor R1, which is connected to the capacitor C. A collector terminal C of the transistor Q2 is connected to ground. The output terminal O is connected to a drain terminal D of the transistor Q1. The drain terminal D of the transistor Q1 further connects to a node H via a resistor R2. A high-level voltage signal is applied to the node H. A source terminal S of the transistor Q1 is connected to ground.

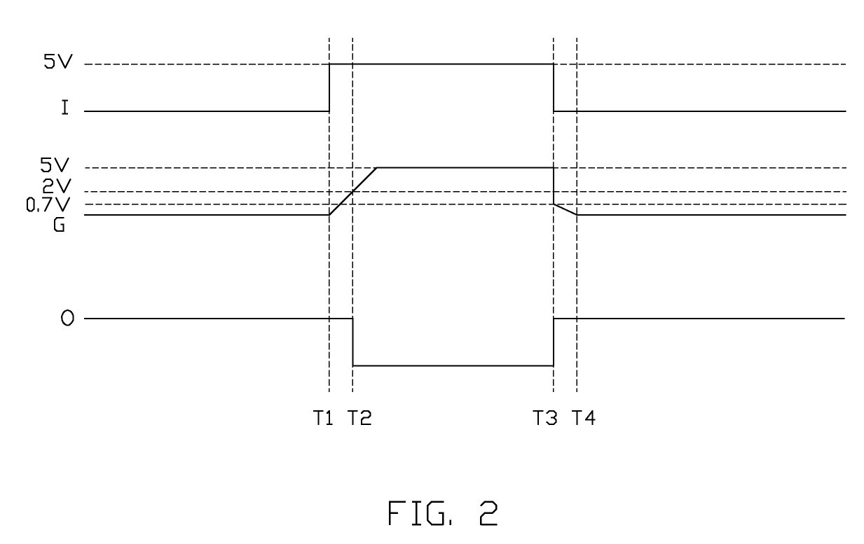

Referring to FIG. 2, at time T1, a high-level voltage signal is input to the input terminal I. The voltage of the base terminal B of the transistor Q2 goes high thereby turning off the transistor Q2. The capacitor C begins to charge, and the voltage of the capacitor C rises. At time T2, the voltage of the capacitor C has risen to 2V, which is equal to a threshold voltage of the transistor Q1. The transistor Q1 turns on to conduct the drain terminal D of the transistor Q1 to ground, and the output terminal O outputs a low-level voltage signal. The output of the low-level voltage signal of the output terminal O is delayed by a period of (T2-T1) relative to the input of the input terminal O.

At time T3, a low-level voltage signal is input to the input terminal I. The voltage of the base terminal B of the transistor Q2 goes low, thereby turning on the transistor Q2. The capacitor C is quickly discharged via the transistor Q2. The voltage of the capacitor C quickly goes below 2V turning off the transistor Q1, and the output terminal O outputs a high-level voltage signal. The output of the high-level voltage signal of the output terminal O is substantially synchronized with the input of the low-level voltage signal of the input terminal I. When the voltage of the capacitor C decreases below 0.7V, the transistor Q2 is turned off, and the capacitor C is then discharged via the resistor R1.

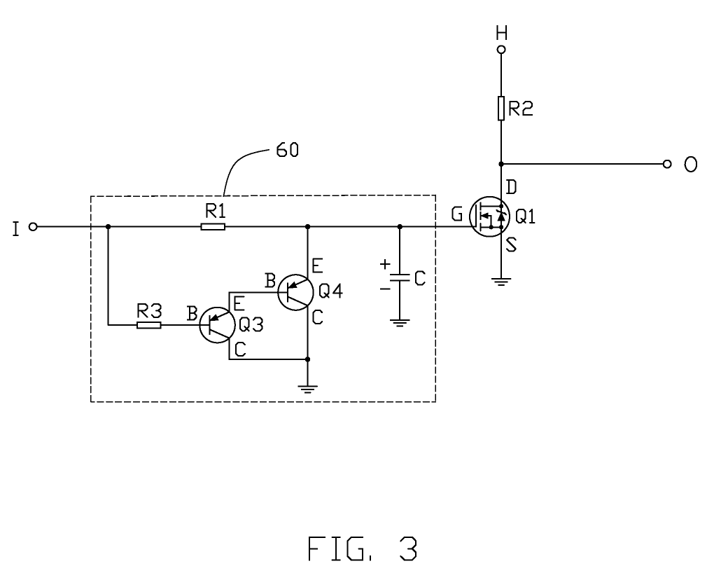

Referring to FIG. 3, a time delay circuit 60 in accordance with a second embodiment of the present invention applied in a circuit is shown. Instead of the transistor Q2 in the previous time delay circuit 50, two linked PNP type transistors Q3 and Q4 are used. A base terminal of the transistor Q3 is connected to the input terminal I via the resistor R3. An emitter terminal of the transistor Q3 is connected to a base terminal of the transistor Q4. A collector terminal C of the transistor Q3 is connected to a collector terminal C of the transistor Q4, which is connected to ground. An emitter terminal of transistor Q4 is connected to the joint node of the resistor R1 and the capacitor C. The transistors Q3 and Q4 connected together in this manner can discharge the capacitor C more quickly than the sole transistor Q2 in the previous embodiment, because the linked transistors Q3 and Q4 have greater current magnification than the sole transistor Q2.

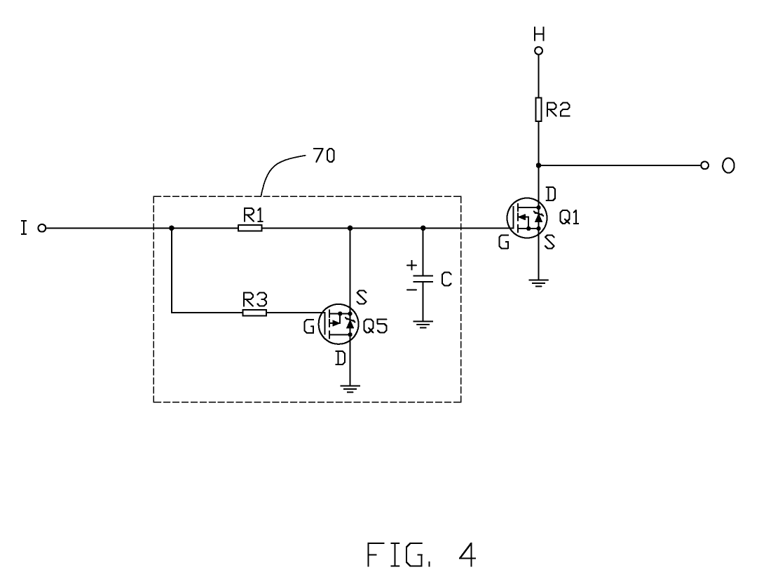

Referring to FIG. 4, a time delay circuit 70 in accordance with a third embodiment of the present invention applied in a circuit is shown. In the time delay circuit 70, an N channel junction field effect transistor Q5 is substituted for the transistor Q2 of the first embodiment. The transistor Q5 can be turned on when a low-level voltage signal is applied thereto, and turned off when a high-level voltage signal is applied, just like the transistor Q2 of the first embodiment. A gate terminal of the transistor Q5 is connected to the input terminal I via the resistor R3, a source terminal is connected to a joint node of the resistor R1 and capacitor C, and a drain terminal is connected to ground. The transistor Q5 functions the same as the transistor Q2 in the first embodiment.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A time delay circuit, comprising:
an RC circuit with a resistor and a capacitor connected; and
a switch comprising a first terminal, a second terminal, and a control terminal for controlling conduction of the first and second terminals, the first terminal connected to an end of the resistor which is connected to the capacitor, the second terminal connected to ground, and the control terminal connected to the other end of the resistor configured for receiving an input signal;
wherein when the input signal changes from logical low to logical high to turn off the switch, the capacitor is charged to a predetermined value with a predetermined rise time beginning from the change of the input signal, and when the input signal changes from logical high to logical low to turn on the switch, the first and second terminals of the switch conduct to quickly discharge the capacitor to the predetermined value substantially synchronized with the change of the input signal.

2. The time delay circuit as described in claim 1, where the switch comprises a PNP type transistor, a base terminal of the transistor acts as the control terminal, an emitter terminal of the transistor acts as the first terminal, and a collector terminal of the transistor acts as the second terminal.

3. The time delay circuit as described in claim 1, wherein the switch comprises two PNP type transistors, a base terminal of one of the two transistors acts as the control terminal, an emitter terminal of the other transistor acts as the first terminal, an emitter terminal of the one transistor is connected to a base terminal of the other transistor, a collector of the one transistor is connected to a collector of the other transistor to serve as the second terminal.

4. The time delay circuit as described in claim 1, wherein the switch is a P channel junction field effect transistor, the control terminal is a gate terminal of the transistor, the first terminal is a source terminal of the transistor, and the second terminal is a drain terminal of the transistor.

5. The time delay circuit as described in claim 1, wherein the control terminal connects to the other end of the resistor via another resistor.

6. A circuit comprising:
an input terminal configured for receiving an input signal and an output terminal configured for outputting an output signal in response to the input signal;
an RC circuit comprising a resistor and a capacitor, one end of the resistor coupled to the input terminal and the other end of the resistor coupled to one end of the capacitor via a node therebetween, the other end of the capacitor coupled to ground;
a switch comprising a first terminal, a second terminal, and a control terminal for controlling conduction of the first and second terminals, the first terminal coupled to the node of the resistor and the capacitor, the second terminal coupled to ground, and the control terminal coupled to the one end of the resistor; and
a transistor comprising a first terminal supplied by a high-level voltage signal, a second terminal coupled to ground, and a control terminal for controlling conduction of the first and second terminals of the transistor, the first terminal being further coupled to the output terminal;
wherein when the input signal changes from a low-level voltage signal to a high-level voltage signal to turn off the switch, the capacitor is charged to a predetermined value within a predetermined rise time to turn on the transistor such that the output terminal changes the voltage level of the output signal after a predetermined delay period equal to the rise time of the capacitor; and
when the input signal changes from a high-level voltage signal to a low-level voltage signal to turn on the switch, the first and second terminals of the switch conduct to quickly discharge the capacitor to the predetermined value to turn off the transistor such that the output terminal changes the voltage level of the output signal substantially synchronized with the change of the input signal.

7. The circuit as described in claim 6, where the switch comprises a PNP type transistor, a base terminal of the transistor acts as the control terminal, an emitter terminal of the transistor acts as the first terminal, and a collector terminal of the transistor acts as the second terminal.

8. The circuit as described in claim 6, wherein the switch comprises two PNP type transistors, a base terminal of one of the two transistors acts as the control terminal, an emitter terminal of the other transistor acts as the first terminal, an emitter terminal of the one transistor is connected to a base terminal of the other transistor, a collector of the one transistor is connected to a collector of the other transistor to serve as the second terminal.

9. The circuit as described in claim 6, wherein the switch is a P channel junction field effect transistor, the control terminal is a gate terminal of the transistor, the first terminal is a source terminal of the transistor, and the second terminal is a drain terminal of the transistor.

10. The circuit as described in claim 6, wherein the control terminal connects to the other end of the resistor via another resistor.

11. The circuit as described in claim 6, wherein the transistor is a N channel junction field effect transistor, a gate terminal of the transistor acts as the control terminal, a drain terminal of the transistor acts as the first terminal, and a source terminal of the transistor acts as the second terminal.
